(19) United States
(12) Patent Application Publication
(10) Pub. No.: US 2026/0333774 A1
(43) Pub. Date: Oct. 22, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: MIN-KUN DAI, HSINCHU CITY (TW); KAI-WEN CHENG, TAICHUNG CITY (TW)

(21) Appl. No.: 19/181,382

(22) Filed: Apr. 17, 2025

(51) Int. Cl. H10D 30/67; H10D 30/01

(52) U.S. Cl. CPC H10D 30/6757; H10D 30/031; H10D 30/6755

(57) ABSTRACT

A semiconductor structure includes a gate electrode, a first dielectric layer over the gate electrode, a channel structure over the first dielectric layer, and a source electrode and a drain electrode over the channel structure. The channel structure includes a pair of barrier layers, a first channel layer and a second channel layer between the pair of the barrier layers, and a second dielectric layer between the first channel layer and the second channel layer. A donor carrier (Nd) concentration of the pair of barrier layers is different from an Nd concentration of the first channel layer, and different from an Nd concentration of the second channel layer.

### BACKGROUND

Thin film transistors (TFTs) made from oxide semiconductor (OS) materials are an advancement in back-end-of-line (BEOL) integration in semiconductor manufacturing, due to their low-temperature processing capability. This feature is essential for preserving the integrity of devices fabricated in front-end-of-line (FEOL) and middle-end-of-line (MEOL) stages, allowing for the fabrication of transistors in a BEOL structure without risking damage to underlying structures. As the semiconductor industry aims to enhance areal density of integrated circuits, ongoing miniaturization individual transistors is beginning to plateau. By moving the fabrication of the transistors from FEOL to the BEOL, manufacturers can optimize chip area and introduce additional functionalities without compromising existing device layers. Therefore, the integration of TFTs in the BEOL structure offers a strategic opportunity to improve device density while ensuring the performance and reliability of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor structure according to aspects of the present disclosure in one or more embodiments.

FIG. 2 is a partially-enlarged view of FIG. 1 according to aspects of the present disclosure in one or more embodiments.

FIG. 3 is a partially-enlarged view of FIG. 1 according to aspects of the present disclosure in one or more embodiments.

FIG. 4 is an energy band diagram of the semiconductor structure according to aspects of the present disclosure in one or more embodiments.

FIG. 5 is a flowchart representing a method for forming a semiconductor structure according to aspects of the present disclosure.

FIGS. 6A to 6K are schematic drawings of a semiconductor structure at various fabrication stages constructed according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" or “about” generally mean within a value or range that can be contemplated by people having ordinary skill in the art. Alternatively, the terms "substantially," "approximately" or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Leakage current and bias/thermal stability are both important issues for oxide semiconductor thin-film transistors (OS TFTs), which are highly sensitive to oxygen vacancies in the active layer, as well as to ambient H₂O and oxygen molecules. To maintain good stability and enhance electrical performance, it is important to mitigate the influence of oxygen vacancy defect states at active layer/gate dielectric interfaces and back-channel layers. A natural a tradeoff between mobility and stability is often found in OS TFT devices. Further, in some comparative approaches, defects found at an interface between a channel layer and a cap layer, and at interface between the channel layer and a gate dielectric layer, may induce metal ion diffusion and lead to adverse impacts on device performance and device reliability.

The present disclosure therefore provides a semiconductor structure and a method for forming the same. The semiconductor structure includes a multilayered structure inserted in a channel layer of a TFT device. The multilayered structure serves as a barrier layer that mitigates diffusion issues and interface defects. In some embodiments, the multilayered structure helps to form a quantum well in the channel layer. Accordingly, device performance and device reliability are both improved.

While the present disclosure discusses aspects of methods of forming a semiconductor structure in the context of a BEOL process or an MEOL process performed after, e.g., a FinFET formation process in FEOL processes, other embodiments may utilize aspects of this disclosure with other semiconductor fabrication processes.

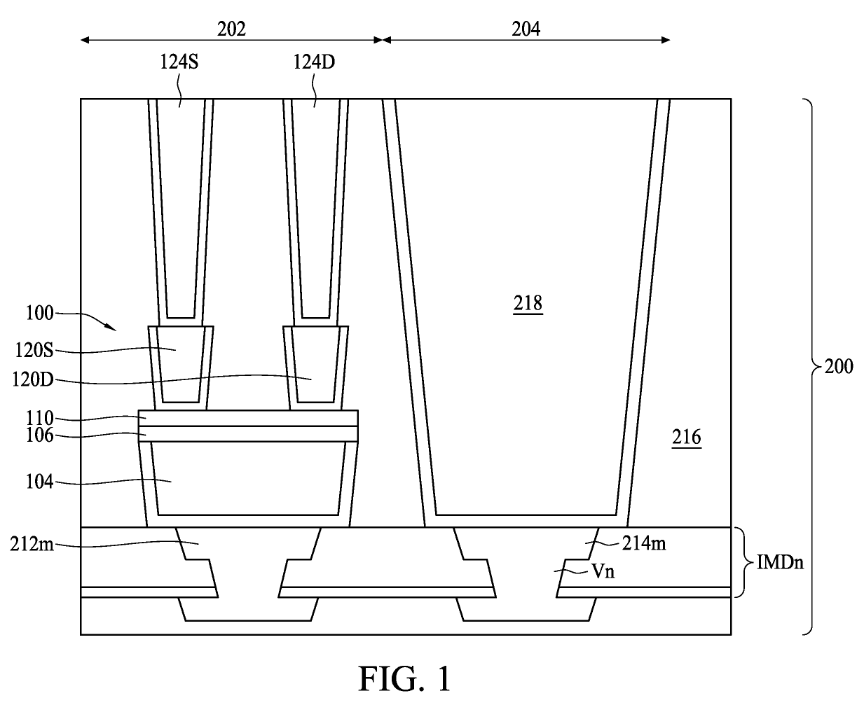

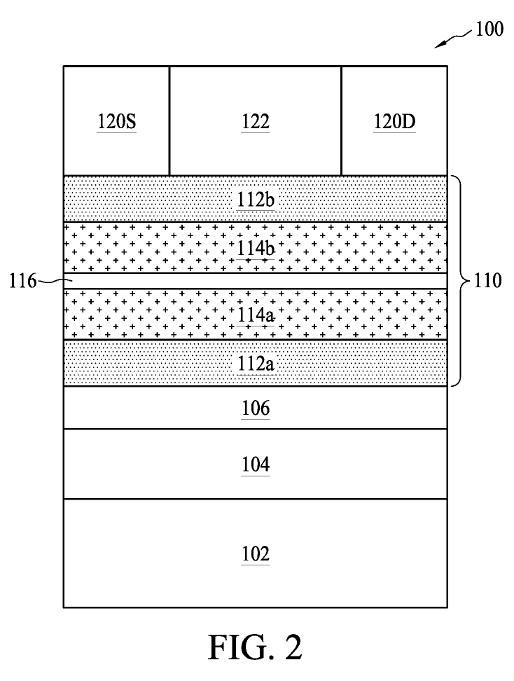

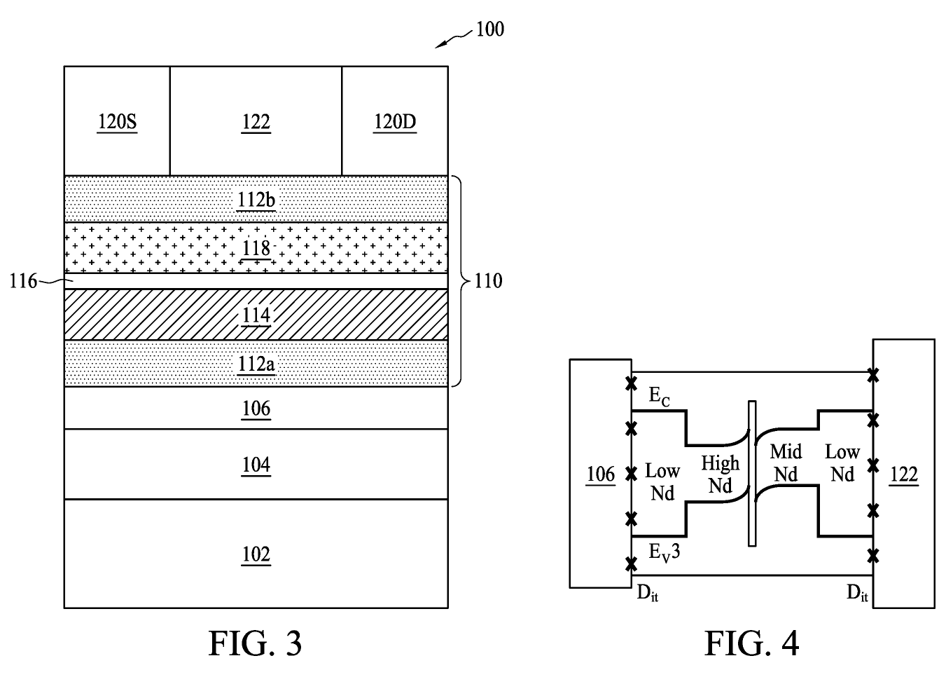

Please refer to FIGS. 1 to 3, wherein FIG. 1 is a schematic cross-sectional view of a semiconductor structure according to aspects of the present disclosure in one or more embodiments, FIG. 2 is a partially-enlarged view of FIG. 1 according to aspects of the present disclosure in one or more embodiments, and FIG. 3 is a partially-enlarged view of FIG. 1 according to aspects of the present disclosure in other embodiments.

In some embodiments, the semiconductor structure 100 may be formed over a substrate (not shown). In some embodiments, the substrate (not shown) may be any type of semiconductor body (including, for example, a semiconductor body formed of silicon (Si), silicon germanium (SiGe), silicon-on-insulator (SOI), or like), such as a semiconductor wafer and/or one or more dies on a wafer, as well as a semiconductor body formed of any other type of semiconductor and/or epitaxial layers, suitable for such application.

In some embodiments, the substrate can include FEOL devices and can be a portion of an IC chip, a system-on-chip (SoC), or a portion of a SoC. In some embodiments, the substrate can be a substrate accommodating FEOL devices such as microprocessors, memories, and/or other IC devices. In some embodiments, the substrate can include various passive and active microelectronic devices, such as resistors, capacitors, inductors, diodes, p-type field-effect transistors (PFETs), n-type field-effect transistors (NFETs), metal-oxide semiconductor field effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, other suitable components, or combinations thereof. The transistors may be planar transistors or multi-gate transistors, such as fin-type FETs (FinFETs).

In some embodiments, a layer of a MEOL interconnect structure (not shown) can be formed over the substrate. The layer of the MEOL interconnect structure includes a plurality of connecting vias (not shown) disposed in an inter-layer dielectric (ILD) layer (not shown). The connecting vias are coupled to the FEOL devices. In some embodiments, the connecting vias can include a via-to-gate (VG), which generally refers to contact with a gate structure. In other embodiments, the connecting via can include a via-to-drain (VD), which generally refers to contact with a source/drain region. Accordingly, the FEOL devices can be electrically connected to a BEOL interconnect structure through a layer of the MEOL interconnect structure.

In some embodiments, a BEOL interconnect structure 200 is formed over the substrate and is electrically connected to the FEOL devices over the substrate. In some embodiments, the BEOL interconnect structure 200 can include a plurality of metallization layers referred to, in ascending order, as the zeroth metallization layer M0, the first metallization layer M1, the (n-1)th metallization layer Mₙ₋₁, the Nth metallization layer Mₙ, and the (Mn+1)th metallization layer Mₙ₊₁, and a plurality of connecting vias referred to as the zeroth connecting via V₀, the first connecting via V₁, and the Nth connecting via Vₙ, wherein n is a positive integer. The (n-1)th metallization layer Mₙ₋₁ and the Nth metallization layer Mₙ can be electrically connected by the Nth connecting via Vₙ. Further, the metallization layer Mₙ and the connecting via Vₙ can be formed in an inter-metal dielectric layer IMDₙ, which provides mechanical support and electrical isolation for the metallization layers Mₙ and the connecting via Vₙ.

In some embodiments, the semiconductor structure 100 is disposed in the BEOL interconnect structure 200. For example but not limited thereto, the semiconductor structure 100 is disposed over the Nth metallization layer Mₙ, as shown in FIG. 1. In some embodiments, the substrate and the BEOL interconnect structure 200 may be defined to have a first region 202 and a second region 204, and the metallization layers Mₙ may be formed in both of the first region 202 and the second region 204. For example, one of the metallization layers Mₙ located in the first region 202 may be referred to as a metallization layer 212m, while the other metallization layer Mₙ located in the second region 204 may be referred to as a metallization layer 214m. In some embodiments, the semiconductor structure 100 is disposed in the first region 202. In such embodiments, the first region 202 may be referred to as a cell region, where the semiconductor structure 100 is located, and the second region 204 may be referred to as a logic region. As shown in FIG. 1, the metallization layer 214min the second region 204 is separated from the semiconductor structure 100 and the metallization layer 212min the first region 202. Another portion 218 of the BEOL interconnect structure 200 may be disposed over and coupled to the metallization layer 214min the second region 204. The portion 218 of the BEOL interconnect structure 200 may be a metallization layer Mₙ₊₁, or a metallization layer Mₙ₊₁ and a connecting via Vₙ₊₁, though not shown. In other embodiments, the portion 218 of the BEOL interconnect structure 200 may include more than metallization layers coupled by connecting vias, depending on various product design. In some embodiments, the semiconductor structure 100 is disposed over and coupled to the metallization layer 212m, but the disclosure is not limited thereto. For example, the semiconductor structure 100 may be disposed over the metallization layer 212m, but coupled to the metallization layer 212m through a connecting via (not shown).

Referring to FIG. 2, the semiconductor structure 100 includes a gate electrode 104 disposed over a supporting structure 102. In some embodiments, the supporting structure 102 is the metallization layer 212m, as mentioned above. In other embodiments, the supporting structure 102 is a connecting via. In still other embodiments, the supporting structure 102 may be an IMD layer of the BEOL interconnect structure 200. The gate electrode 104 may include a conductive material. In some embodiments, the conductive material of the gate electrode 104 may have a metal work function that is configured to increase a threshold voltage of the semiconductor structure 100, thereby further mitigating a current flowing through a channel region. In some embodiments, the gate electrode 104 may include platinum (Pt), titanium (Ti), titanium nitride (TiN), tantalum (Ta), tantalum nitride (TaN), tungsten (W), tungsten nitride (WN), copper (Cu), gold (Au), zinc (Zn), aluminum (Al), iron (Fe), nickel (Ni), beryllium (Be), chromium (Cr), cobalt (Co), antimony (Sb), iridium (Ir), molybdenum (Mo), osmium (Os), thorium (Th), vanadium (V), or a combination thereof. In some embodiments, the gate electrode 104 may include a buried gate structure, but the disclosure is not limited thereto. In such embodiments, a top surface of the gate electrode 104 may be aligned with or coplanar with a top surface of the supporting structure 102, though not shown. A thickness of the gate electrode 104 may be between approximately 30 nanometers (nm) and approximately 600 nanometers, but the disclosure is not limited thereto.

The semiconductor structure 100 includes a gate dielectric layer 106 disposed over the gate electrode 104. The gate dielectric layer 106 may include any suitable dielectric material such as silicon oxide (SiO₂), or the like, or a high-k dielectric material such as silicon nitride (SiN₄), hafnium oxide (HfO₂), hafnium silicon oxide (HfSiO), hafnium tantalum oxide (HfTaO), hafnium titanium oxide (HfTiO), hafnium zirconium oxide (Hf_{0.5}Zr_{0.5}O₂), tantalum oxide (Ta₂O₅), aluminum oxide (Al₂O₃), hafnium dioxide-alumina (HfO₂—Al₂O₃), zirconium oxide (ZrO₂), or the like. Other suitable dielectric materials may also be within the contemplated scope of disclosure.

The semiconductor structure 100 includes a multilayered channel structure 110 disposed over the gate dielectric layer 106. The multilayered channel structure 110 includes a pair of barrier layers 112a and 112b, as shown in FIGS. 2 and 3. In some embodiments, the barrier layer 112aand the barrier layer 112b include a same material. In some alternative embodiments, the barrier layer 112a and the barrier layer 112b include different materials. In some embodiments, each of the barrier layers 112aand 112b includes oxide semiconductor materials. Exemplary oxide semiconductor materials that may be used for the barrier layers 112aand 112binclude, but are not limited to, indium gallium zinc oxide (InGaZnO, IGZO), indium tungsten oxide, indium zinc oxide, indium tin oxide, gallium oxide, indium oxide, doped zinc oxide, doped indium oxide, doped cadmium oxide, and various other doped variants derived therefrom. In some embodiments, each of the barrier layers 112aand 112b includes the doped oxide semiconductor material. For example but not limited thereto, each of the barrier layers 112a and 112bmay include silicon-doped InGaZnO, hafnium-doped InGaZnO, tungsten-doped InGaZnO, and titanium-doped InGaZnO. Bond dissociation energy between the abovementioned dopants and oxygen is greater than that between InGaZn-O; therefore, the abovementioned dopants are expected to suppress oxygen vacancy. Accordingly, the barrier layers 112aand 112bare referred to as low donor carrier (Nd) concentration layers.

Referring to FIG. 2, in some embodiments, the multilayered channel structure 110 further includes channel layers 114a and 114b disposed between the barrier layers 112a and 112b. The channel layer 114aand the channel layer 114binclude a same material. In some embodiments, the channel layer 114a and the channel layer 114b include oxide semiconductor materials. Exemplary oxide semiconductor materials that may be used for the channel layers 114aand 114b include, but are not limited to, InGaZnO, indium tungsten oxide, indium zinc oxide, indium tin oxide, gallium oxide, indium oxide, doped zinc oxide, doped indium oxide, doped cadmium oxide, and various other doped variants derived therefrom. A donor carrier concentration of each of the channel layers 114a and 114b is greater than donor carrier concentrations of the barrier layers 112a and 112b. In such embodiments, the channel layers 114aand 114b are referred to as high Nd concentration layers. In some embodiments, a thickness of the barrier layer 112a, a thickness of the channel layer 114a, a thickness of the channel layer 114b, and a thickness of the barrier layer 112b may be similar. In other embodiments, the thickness of the channel layer 114a and the thickness of the channel layer 114b are respectively greater than the thickness of the barrier layer 112a, and respectively greater than the thickness of the barrier layer 112b.

Referring to FIG. 3, in some embodiments, the multilayered channel structure 110 includes a channel layer 114 disposed between the barrier layers 112a and 112b, and another channel layer 118 disposed between the channel layer 114 and the barrier layer 112b. In some embodiments, the channel layer 114 and the channel layer 118 may include different materials. In other embodiments, the channel layer 114 and the channel layer 118 may include a same material but with different dopants, different dopant concentrations, or different element ratios. In some embodiments, the channel layer 114 and the channel layer 118 may include oxide semiconductor materials. Exemplary oxide semiconductor materials that may be used for the channel layers 114 and 118 include, but are not limited to, InGaZnO, indium tungsten oxide, indium zinc oxide, indium tin oxide, gallium oxide, indium oxide, doped zinc oxide, doped indium oxide, doped cadmium oxide, and various other doped variants derived therefrom. A donor carrier concentration of the channel layer 114 and a donor carrier concentration of the channel layer 118 are greater than the donor carrier concentrations of the barrier layers 112a and 112b. In some embodiments, by adjusting dopant concentrations of the channel layers 114 and 118, the channel layer 114 is formed to be a high Nd concentration layer, while the channel layer 118 is formed to be a middle Nd concentration layer. In other embodiments, when both the channel layers 114 and 118 include, for example but not limited thereto, InGaZnO, the channel layer 114 can be made to be a high Nd concentration layer, and the channel layer 118 can be made to a be a middle Nd concentration layer by adjusting an element ratio such as In/Ga/Zn/O ratio. For example, an oxygen concentration of the channel layer 114 may be made greater than that of the channel layer 118, such that the channel layer 114 is a high Nd concentration layer, and the channel layer 118 is a middle Nd concentration layer. In some embodiments, a thickness of the barrier layer 112a, a thickness of the channel layer 114, a thickness of the channel layer 118, and a thickness of the barrier layer 112b may be similar. In other embodiments, the thickness of the channel layer 114 and the thickness of the channel layer 118 are respectively greater than the thickness of the barrier layer 112a, and respectively greater than the thickness of the barrier layer 112b.

Referring to FIG. 2, in some embodiments, the multilayered channel structure 110 includes a dielectric layer 116 disposed between the high Nd concentration layers (i.e., the channel layer 114aand the channel layer 114b). Referring to FIG. 3, in some embodiments, the multilayered channel structure 110 includes a dielectric layer 116 disposed between the high Nd concentration layer (i.e., the channel layer 114) and the middle Nd concentration layer (i.e., the channel layer 118). In such embodiments, it can be said that the high Nd concentration layer 114 is disposed between the gate dielectric layer 106 and the dielectric layer 116. The dielectric layer 116 may include silicon oxide (SiO_{X}), aluminum oxide (Al₂O₃), hafnium oxide (HfO₂), zirconium oxide (ZrO₂), or tantalum oxide (Ta₂O₅). In some embodiments, a thickness of the dielectric layer 116 is between approximately 0.1 nanometers and approximately tens of nanometers, but the disclosure is not limited thereto.

Referring to FIGS. 2 and 3, the semiconductor structure 100 further includes a source electrode 120S and a drain electrode 120D disposed over the multilayered channel structure 110. Further, the source electrode 120S and the drain electrode 120D are separated from each other. In some embodiments, the semiconductor structure 100 further includes a dielectric layer 122 or a cap layer 122 separating the source electrode 120S from the drain electrode 120D. In some embodiments, each of the source electrode 120S and the drain electrode 120D includes platinum (Pt), ruthenium (Ru), palladium (Pd), tungsten (W), or gold (Au), but the disclosure is not limited thereto.

Referring back to FIG. 1, the semiconductor structure 100 further includes a source via connector 124S and a drain via connector 124D disposed over the multilayered channel structure 110. The source via connector 124S is coupled to the source electrode 120S, and the drain via connector 124D is coupled to the drain electrode 120D. Further, the source via connector 124S and the drain via connector 124D are separated from each other by a dielectric layer 216. In some embodiments, the dielectric layer 216 may be a part of the inter-metal dielectric (IMD) structure in the BEOL interconnect structure 200. The IMD structure may include one or more dielectric layers, and the dielectric layer may include silicon oxide, silicon nitride, carbon doped silicon dioxide, BSG, PSG, BPSG, FSG, USG, a porous dielectric material, or the like. In some embodiments, the dielectric layer 216 and the cap layer 122 include different materials. In alternative embodiments, the dielectric layer 216 and the cap layer 122 include a same material, as shown in FIG. 1.

Referring to FIG. 4, which is an energy band diagram of the semiconductor structure 100 according to aspects of the present disclosure in one or more embodiments, the low Nd concentration barrier layers 112a and 112b, the high Nd concentration channel layer 114, the dielectric layer 116 and the middle Nd concentration layer 118 of the multilayered channel structure 100 help to improve the device performance and mitigate interface defects by: (1) effective confining of carrier conduction by the high Nd concentration layer 114 and the middle Nd concentration layer 118, and mitigation of a metal ion diffusion issue by the dielectric layer 116, resulting in effective formation of a 2D quantum well; and (2) mitigation of a carrier trapping issue by the low Nd concentration barrier layer 112a at an interface between the gate dielectric layer 106 and the multilayered channel structure 110, and mitigation of the carrier trapping issue by the low Nd concentration barrier layer 112b at an interface between the cap layer 122 and the multilayered channel structure 110. Accordingly, the device performance is improved due to the 2D quantum well and the mitigation of the metal ion diffusion issue, and device reliability is improved due to the mitigation of the carrier trapping issue.

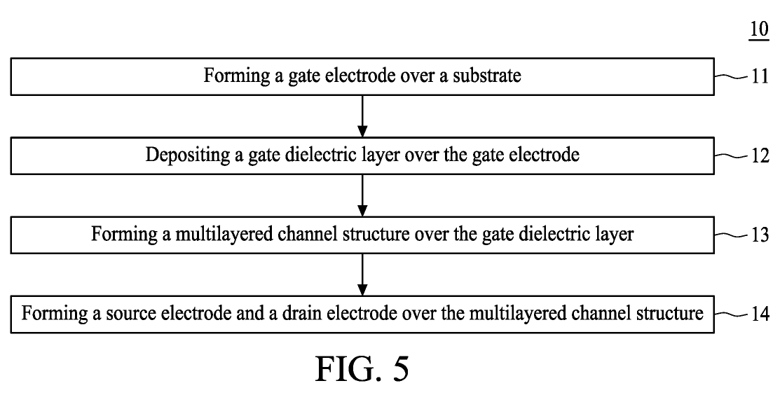

FIG. 5 is a flowchart representing a method for forming a semiconductor structure 10 in accordance with aspects of the present disclosure. The method 10 includes a number of operations (11, 12, 13 and 14). The method 10 is further described according to one or more embodiments. It should be noted that the operations of the method 10 may be rearranged or otherwise modified within the scope of the various aspects. It should be further noted that additional processes may be provided before, during, and after the method 10, and that some other processes may be only briefly described herein. Thus, other implementations are possible within the scope of the various aspects described herein.

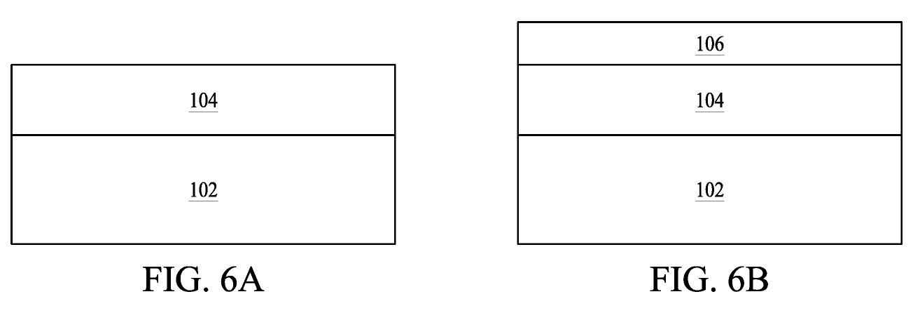

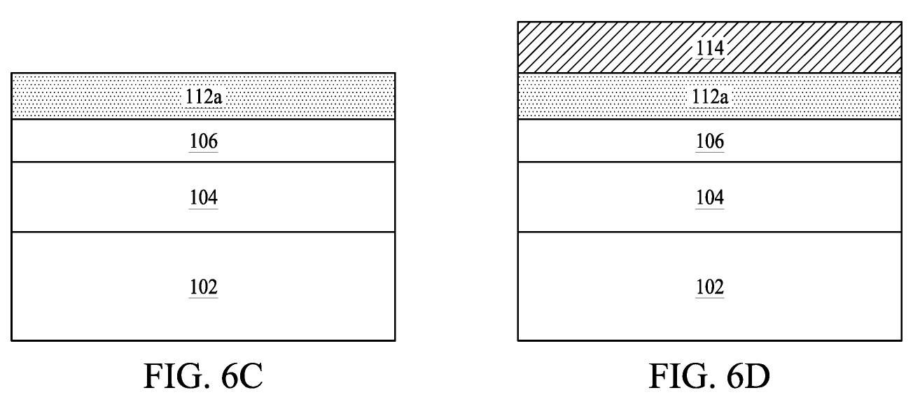

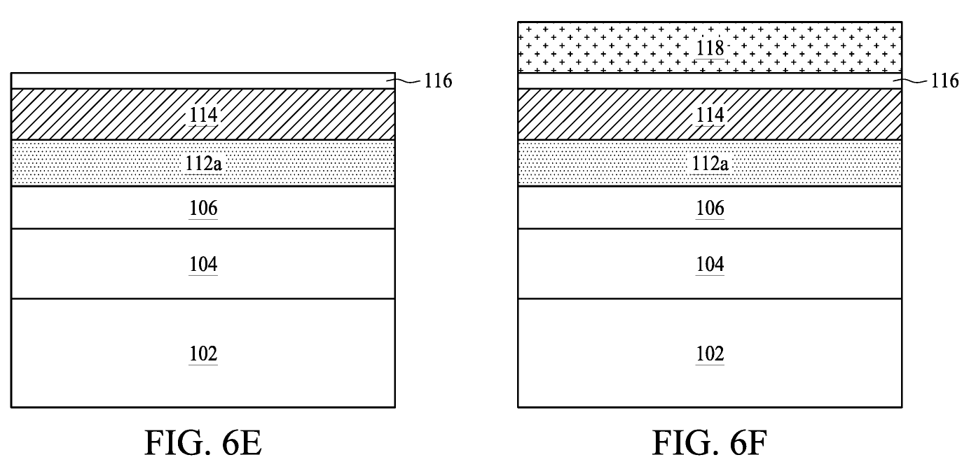

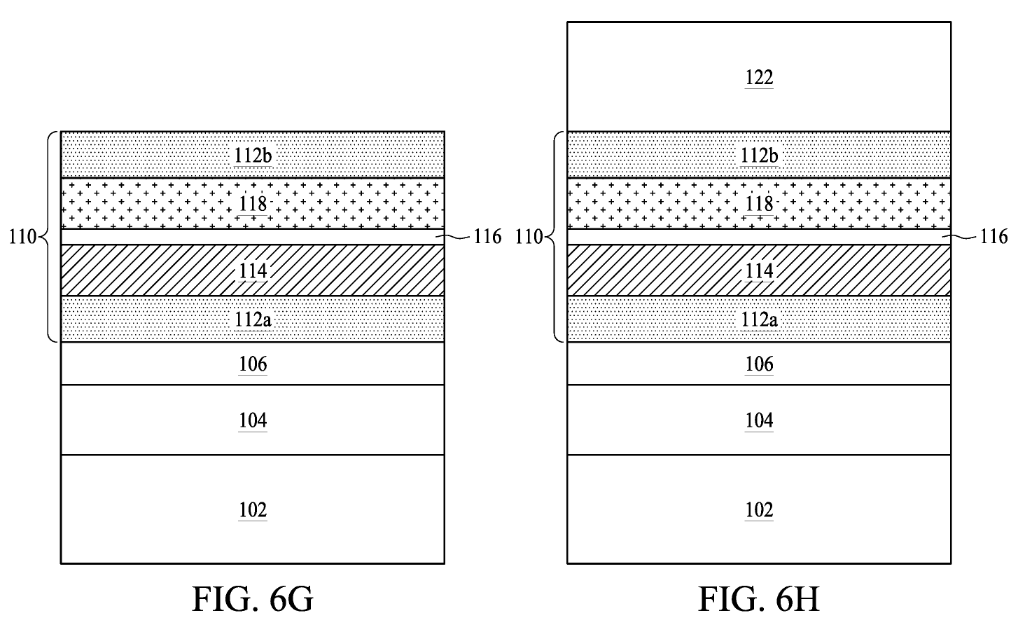

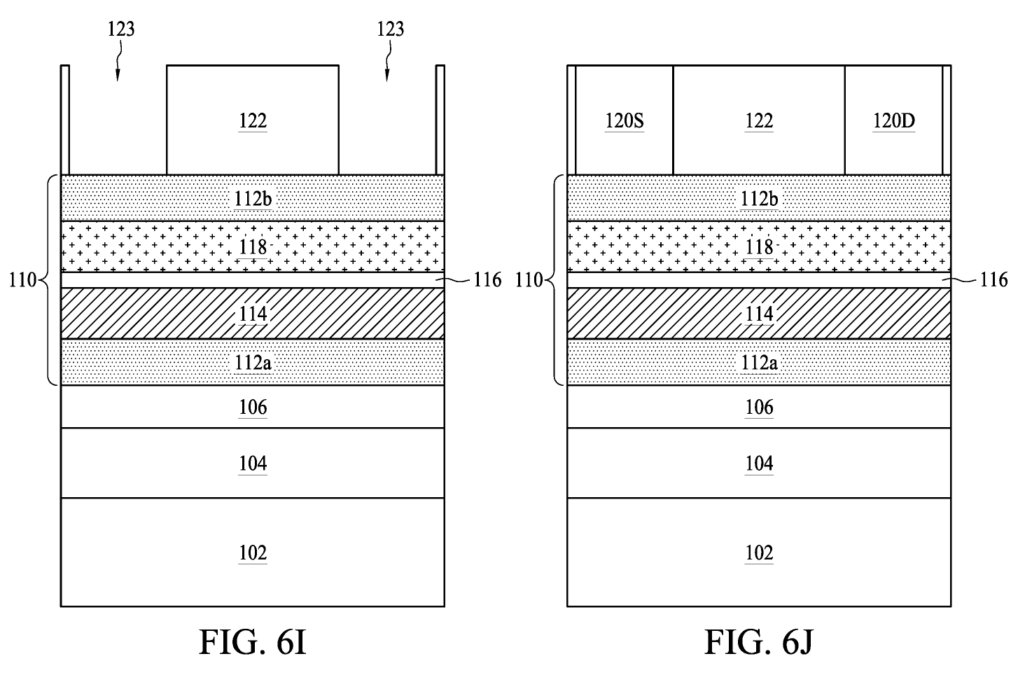

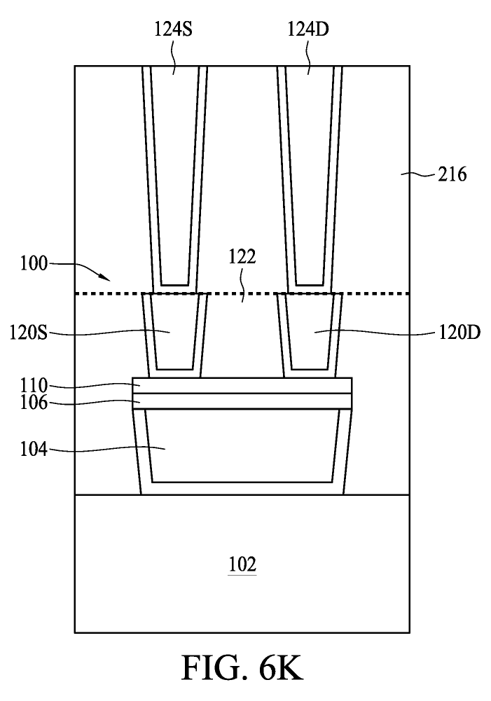

In some embodiments, a semiconductor structure 100 may be formed by the method 10. FIGS. 6A to 6K are schematic drawings of the semiconductor structure 100 at various fabrication stages constructed according to aspects of the present disclosure in one or more embodiments.

Referring to FIG. 6A, in some embodiments, in operation 11, a gate electrode 104 is formed over a substrate 102, which may be referred to as a supporting structure. The substrate 102 may include FEOL devices, MEOL elements, and a BEOL interconnect structure 200. In some embodiments, the substrate 102 may be a part of the BEOL interconnect structure 200. In such embodiments, the substrate 102 may include a metallization layer 212m, a connecting via, or an IMD layer of the BEOL interconnect structure 200. In some embodiments, when the substrate 102 is a part of the BEOL interconnect structure 200, the gate electrode 104 is formed in a cell region 202, as shown in FIG. 1. A material of the gate electrode 104 may be similar to materials of the gate electrodes described above; therefore, repeated descriptions are omitted. In various embodiments, the gate electrode 104 may be formed using one or more deposition processes (e.g., atomic layer deposition (ALD) processes, chemical vapor deposition (CVD) processes, plasma-enhanced chemical vapor deposition (PE-CVD) processes, or the like), and various patterning processes.

In some embodiments, the forming of the gate electrode 104 may include forming a dielectric layer (not shown) over the substrate 102, and patterning the dielectric layer to form a trench (not shown). The gate electrode 104 is formed in the trench. In some embodiments, a top surface of the gate electrode 104 may be aligned or flush with a top surface of the dielectric layer, though not shown.

Referring to FIG. 6B, in some embodiments, in operation 12, a gate dielectric layer 106 is formed over the gate electrode 104. For example, the gate dielectric layer 106 is deposited over the gate electrode 104. A material of the gate dielectric layer 106 may be similar to materials of the gate electric layers described above, and repeated descriptions are omitted. In various embodiments, the gate dielectric layer 106 may be formed using one or more deposition processes (e.g., ALD processes, CVD processes, physical vapor deposition (PVD) processes, PE-CVD processes, or the like), and various patterning processes.

In some embodiments, in operation 13, a multilayered channel structure 110 is formed over the gate dielectric layer 106. In some embodiments, operation 13 includes further operations. For example, referring to FIG. 6C, a first oxide semiconductor layer 112a is formed over the gate dielectric layer 106. For example, the first oxide semiconductor layer 112a is deposited over the gate dielectric layer 106. A material of the first oxide semiconductor layer 112a is similar to that of the barrier layer 112a described above, and repeated descriptions are omitted. The first oxide semiconductor layer 112ahas a first Nd concentration. In some embodiments, by doping the first oxide semiconductor layer 112a, the first Nd concentration of the first oxide semiconductor layer 112a is adjusted. In some embodiments, dopants used to reduce the first Nd concentration may include silicon hafnium tungsten and titanium, but the disclosure is not limited thereto.

Referring to FIG. 6D, a second oxide semiconductor layer 114 or 114ais formed over the first oxide semiconductor layer 112a. For example, the second oxide semiconductor layer 114 or 114ais deposited over the first oxide semiconductor layer 112a. The second oxide semiconductor layer 114 or 114ahas a second Nd concentration. A material of the second oxide semiconductor layer 114 or 114ais similar to that of the channel layer 114 or 114adescribed above, and repeated descriptions are omitted. In some embodiments, the first oxide semiconductor layer 112a and the second oxide semiconductor layer 114 or 114a may include same a material, such as InGaZnO. However, unlike the first oxide semiconductor layer 112a, which includes dopants to reduce the first Nd concentration, the second oxide semiconductor layer 114 or 114ahas various element ratios (i.e., a ratio of In:Ga:ZnO) that increases the second Nd concentration. Accordingly, the second Nd concentration of the second oxide semiconductor layer 114 or 114ais made greater than the first Nd concentration of the first oxide semiconductor layer 112a.

Referring to FIG. 6E, a dielectric layer 116 is formed over the second oxide semiconductor layer 114 or 114a. For example, the dielectric layer 116 is deposited over the second oxide semiconductor layer 114 or 114a. A material of the dielectric layer 116 is similar to that of the dielectric layer 116 described above, and repeated descriptions are omitted. In various embodiments, the dielectric layer 116 may be formed using one or more deposition processes (e.g., ALD processes, CVD processes, PVD processes, PE-CVD processes, or the like), and various patterning processes. In some embodiments, a thickness of the dielectric layer 116 is made less than that of previously formed layers (i.e., the first and second oxide semiconductor layers 112a and 114), and less than that of the subsequently formed layers. In such embodiments, the dielectric layer 116 may be referred to as an ultra-thin dielectric layer.

Referring to FIG. 6F, a third oxide semiconductor layer 114bor 118 is formed over the dielectric layer 116. For example, the third oxide semiconductor layer 114b or 118 is deposited over the dielectric layer 116. The third oxide semiconductor layer 114bor 118 has a third Nd concentration. In some embodiments, the third oxide semiconductor layer 114b may include a material same as that of the second oxide semiconductor layer 114a, and a same element ratio as that of the second oxide semiconductor layer 114a. In such embodiments, the third Nd concentration is equal to the second Nd concentration. However, in other embodiments, the second oxide semiconductor layer 114 and the third oxide semiconductor layer 118 may include a same material, such as InGaZnO, but with different element ratios. For example, an oxygen ratio in the second oxide semiconductor layer 114 is greater than that in the third oxide semiconductor layer 118. Accordingly, the second Nd concentration of the second oxide semiconductor layer 114 is greater than the third Nd concentration of the third oxide semiconductor layer 118. In such embodiments, the third Nd concentration of the third oxide semiconductor 118 can be less than the second Nd concentration of the second oxide semiconductor layer 114. However, the third Nd concentration of the third oxide semiconductor layer 118 is greater than the first Nd concentration of the first oxide semiconductor layer 112a.

Referring to FIG. 6G, a fourth oxide semiconductor layer 112b is formed over the third oxide semiconductor layer 114b or 118. For example, the fourth oxide semiconductor layer 112b is deposited over the third oxide semiconductor layer 114b or 118. A material of the fourth oxide semiconductor layer 112b is similar to that of the barrier layer 112b described above; and repeated descriptions are omitted. The fourth oxide semiconductor layer 112bhas a fourth Nd concentration. In some embodiments, by doping the fourth oxide semiconductor layer 112b, the fourth Nd concentration of the fourth oxide semiconductor layer 112b is adjusted. In some embodiments, dopants used to reduce the fourth Nd concentration may include silicon hafnium tungsten and titanium, but the disclosure is not limited thereto. In some embodiments, the fourth Nd concentration of the fourth oxide semiconductor layer 112b is less than the third Nd concentration of the third oxide semiconductor layer 118 or 114b, and less than the second Nd concentration of the second oxide semiconductor layer 114 or 114a. Further, the fourth Nd concentration of the fourth oxide semiconductor layer 112b may be equal to the first Nd concentration of the first oxide semiconductor layer 112a. In such embodiments, the third Nd concentration of the third oxide semiconductor layer 118 may be between the second Nd concentration of the first oxide semiconductor layer 114 or 114band the fourth Nd concentration of the fourth oxide semiconductor layer 112b, and between the first Nd concentration of the third oxide semiconductor layer 112a and the second Nd concentration of the second oxide semiconductor layer 114 or 114b, therefore the third oxide semiconductor layer 118 may be referred to as a middle Nd concentration layer.

In some embodiments, patterning processes may be performed after the forming of the fourth oxide semiconductor layer 112b, thereby forming a multilayered channel structure 110 including the first oxide semiconductor layer 112a, the second oxide semiconductor layer 114a or 114, the dielectric layer 116, the third oxide semiconductor layer 114b or 118, and the fourth oxide semiconductor layer 112b. In some embodiments, the multilayered channel structure 110 includes a pair of low Nd concentration barrier layers (i.e., the first oxide semiconductor layer 112aand the fourth oxide semiconductor layer 112b), a pair of high Nd concentration channel layers (i.e., the second oxide semiconductor layer 114aand the third oxide semiconductor layer 114b) inserted between the pair of low Nd concentration barrier layer 112a and 112b, and a dielectric layer 116 inserted between the pair of high Nd concentration channel layers 114a and 114b. In other embodiments, the multilayered channel structure 110 includes a pair of low Nd concentration barrier layers (i.e., the first oxide semiconductor layer 112aand the fourth oxide semiconductor layer 112b), a high Nd concentration channel layer (i.e., the second oxide semiconductor layer 114) and a middle concentration channel layer (i.e., the third oxide semiconductor layer 118) inserted between the pair of low Nd concentration barrier layer 112a and 112b, and a dielectric layer 116 inserted between the high Nd concentration channel layer 114 and the middle Nd concentration channel layer 118.

In some embodiments, in operation 14, a source electrode and a drain electrode are formed over the multilayered channel structure 110. In some embodiments, operation 14 includes further operations. For example, referring to FIG. 6H, a dielectric layer 122 may be formed over the multilayered channel structure 110. In some embodiments, the dielectric layer 122 may include materials same as IMD materials in the BEOL interconnect structure 200, but the disclosure is not limited thereto.

Referring to FIG. 6I, in some embodiments, the dielectric layer 122 is patterned to form openings 123 that expose portions of the multilayered channel structure 110. Referring to FIG. 6J, in some embodiments, a conductive material is formed to fill the openings 123. In some embodiments, a barrier layer (not shown) may be formed prior to the forming of the conductive material. In some embodiments, the conductive material may include metals such as TiN, Mo, W, or Al, but the disclosure is not limited thereto. A planarization is performed to remove superfluous material, thereby forming the source electrode 120S and the drain electrode 120D.

Referring to FIG. 6K, in some embodiments, another dielectric layer 216 is formed over the substrate 102. Subsequently, a plurality of via connectors are formed in the dielectric layer 216. The via connectors may include a source via connector 124S and a drain via connector 124D. As shown in FIG. 6K, the source via connector 124S is coupled to the source electrode 120S, and the drain via connector 124D is coupled to the drain electrode 120D. The source via connector 124S provides an electrical connection between the source electrode 120S and an upper metallization layer, and the drain via connector 124D provides an electrical connection between the drain electrode 120D and another metallization layer, though not shown.

In some embodiments, after the forming of the via connectors 124S and 124D, BEOL processes may be performed to form connecting vias and metallization layers in the dielectric layer 216.

Accordingly, the present disclosure provides a semiconductor structure and a method for forming the same. The semiconductor structure includes a multilayered structure inserted in a channel layer of a TFT device. The multilayered structure serves as a barrier layer that mitigates diffusion issues and interface defects. In some embodiments, the multilayered structure helps to form a quantum well in the channel layer. Accordingly, device performance and device reliability are both improved.

In some embodiments, a semiconductor structure is provided. The semiconductor structure includes a gate electrode, a first dielectric layer over the gate electrode, a channel structure over the first dielectric layer, and a source electrode and a drain electrode over the channel structure. The channel structure includes a pair of barrier layers, a first channel layer and a second channel layer between the pair of the barrier layers, and a second dielectric layer between the first channel layer and the second channel layer. A donor carrier (Nd) concentration of the pair of barrier layers is different from an Nd concentration of the first channel layer, and different from a Nd concentration of the second channel layer.

In some embodiments, a method for forming a semiconductor structure is provided. The method includes following operations. A gate electrode is formed over a substrate. A gate dielectric layer is formed over the gate electrode. A multilayered channel structure is formed over the gate dielectric layer. The multilayered channel structure includes a pair of barrier layers, a first channel layer and a second channel layer between the pair of barrier layers, and a dielectric layer between the first channel layer and the second channel layer. A source electrode and a drain electrode are formed over the multilayered channel structure. An Nd concentration of the pair of barrier layers is less than an Nd concentration of the first channel layer, and less than an Nd concentration of the second channel layer.

In some embodiments, a method for forming a semiconductor structure is provided. The method includes following operations. A gate electrode is formed over a substrate. A gate dielectric layer is formed over the gate electrode. A first oxide semiconductor layer is formed over the gate dielectric layer. The first oxide semiconductor layer has a first Nd concentration. A second oxide semiconductor layer is formed over the first oxide semiconductor layer. The second oxide semiconductor layer has a second Nd concentration greater than the first Nd concentration. A dielectric layer is formed over the second oxide semiconductor layer. A third oxide semiconductor layer is formed over the dielectric layer. The third oxide semiconductor layer has a third Nd concentration greater than the first Nd concentration. A fourth oxide semiconductor layer is formed over the third oxide semiconductor layer. The fourth oxide semiconductor layer has a fourth Nd concentration less than the second Nd concentration, and less than the third Nd concentration. A source electrode and a drain electrode are formed over the fourth oxide semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a gate electrode;
a first dielectric layer over the gate electrode;
a channel structure over the first dielectric layer, wherein the channel structure comprises:
a pair of barrier layers;
a first channel layer and a second channel layer between the pair of the barrier layers; and
a second dielectric layer between the first channel layer and the second channel layer; and
a source electrode and a drain electrode over the channel structure,
wherein a donor carrier concentration of the pair of barrier layers is different from a donor carrier concentration of the first channel layer, and different from a donor carrier concentration of the second channel layer.

2. The semiconductor structure of claim 1, wherein the donor carrier concentration of the pair of barrier layers is less than the donor carrier concentration of the first channel layer, and less than the donor carrier concentration of the second channel layer.

3. The semiconductor structure of claim 1, wherein the first channel layer and the second channel layer comprise a same material.

4. The semiconductor structure of claim 1, wherein the first channel layer and the second channel layer comprise different materials.

5. The semiconductor structure of claim 4, wherein the donor carrier concentration of the first channel layer is greater than the donor carrier concentration of the second channel layer.

6. The semiconductor structure of claim 5, wherein the first channel layer is between the second channel layer and the first dielectric layer.

7. The semiconductor structure of claim 1, further comprising a third dielectric layer over the channel structure, and between the source electrode and the drain electrode.

8. The semiconductor structure of claim 1, further comprising:
a first metallization layer under and coupled to the gate electrode;
a source via connector over and coupled to the source electrode; and
a drain via connector over and coupled to the drain electrode.

9. The semiconductor structure of claim 8, further comprising a second metallization layer, wherein the second metallization layer is separated from the first metallization layer.

10. A method for forming a semiconductor structure, comprising:
forming a gate electrode over a substrate;
depositing a gate dielectric layer over the gate electrode;
forming a multilayered channel structure over the gate dielectric layer, wherein the multilayered channel structure comprises a pair of barrier layers, a first channel layer and a second channel layer between the pair of barrier layers, and a dielectric layer between the first channel layer and the second channel layer; and
forming a source electrode and a drain electrode over the multilayered channel structure,
wherein a donor carrier concentration of the pair of barrier layers is less than a donor carrier concentration of the first channel layer, and less than a donor carrier concentration of the second channel layer.

11. The method of claim 10, wherein the first channel layer and the second channel layer comprise a same material.

12. The method of claim 10, wherein the first channel layer and the second channel layer comprise different materials.

13. The method of claim 12, wherein the donor concentration of the first channel layer is greater than the donor concentration of the second channel layer.

14. The method of claim 13, wherein the first channel layer is between second channel layer and the gate dielectric layer.

15. The method of claim 10, further comprising:
forming a first dielectric layer over the multilayered channel structure; and
patterning the first dielectric layer to form openings exposing portions of the multilayered channel structure,
wherein the source electrode and the drain electrode are formed in the openings.

16. The method of claim 15, further comprising:
forming a second dielectric layer over the first dielectric layer; and
forming via connectors in the second dielectric layer,
wherein via connectors are coupled to the source electrode and the drain electrode, respectively.

17. A method for forming a semiconductor structure, comprising:
forming a gate electrode over a substrate;
depositing a gate dielectric layer over the gate electrode;
depositing a first oxide semiconductor layer over the gate dielectric layer, wherein the first oxide semiconductor layer has a first donor carrier concentration;
depositing a second oxide semiconductor layer over the first oxide semiconductor layer, wherein the second oxide semiconductor layer has a second donor carrier concentration greater than the first donor carrier concentration;
depositing a dielectric layer over the second oxide semiconductor layer;
depositing a third oxide semiconductor layer over the dielectric layer, wherein the third oxide semiconductor layer has a third donor carrier concentration greater than the first donor carrier concentration;
depositing a fourth oxide semiconductor layer over the third oxide semiconductor layer, wherein the fourth oxide semiconductor layer has a fourth donor carrier concentration less than the second donor carrier concentration, and less than the third donor carrier concentration; and
forming a source electrode and a drain electrode over the fourth oxide semiconductor layer.

18. The method of claim 17, wherein the second donor carrier concentration is equal to the third donor carrier concentration.

19. The method of claim 17, wherein the second donor carrier concentration is greater than the third donor carrier concentration.

20. The method of claim 17, wherein the fourth donor carrier concentration is equal to the first donor carrier concentration.
